(19) United States
(12) Patent Application Publication
(10) Pub. No.: US 2026/0056079 A1
(43) Pub. Date: Feb. 26, 2026

(54) SYSTEMS AND METHODS FOR LEAK DETECTION IN LIQUID-COOLED INFORMATION HANDLING SYSTEMS

(71) Applicant: Dell Products L.P., Round Rock, TX (US)

(72) Inventors: Eduardo ESCAMILLA, Round Rock, TX (US); Michael J. STUMPF, Cedar Park, TX (US); Sandor FARKAS, Round Rock, TX (US)

(73) Assignee: Dell Products L.P., Round Rock, TX (US)

(21) Appl. No.: 18/815,357

(22) Filed: Aug. 26, 2024

(51) Int. Cl. G01M 3/16; G06F 1/20; H05K 7/20

(52) U.S. Cl. CPC G01M 3/165; G06F 1/20; H05K 7/20272

(57) ABSTRACT

An information handling system may include an information handling resource, a liquid cooling system for providing cooling of the information handling resource, and a leak detection system for detecting a leak of fluid from the liquid cooling system. The leak detection system may include a leak detection circuit formed into a helical shape and having at least one moisture-sensitive portion configured to detect the presence of moisture proximate to the leak detection circuit and circuitry configured to communicate one or more electrical signals indicative of the presence or absence of moisture proximate to the leak detection circuit and a moisture wicking material mechanically coupled to the leak detection circuit and configured to transport moisture within the moisture wicking material to the at least one moisture-sensitive portion of the leak detection circuit.

### TECHNICAL FIELD

The present disclosure relates in general to information handling systems, and more particularly to leak detection in liquid-cooled information handling systems.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

To control temperature of components of an information handling system, an air mover may direct air over one or more heatsinks thermally coupled to individual components. Traditional approaches to cooling components may include a “passive” cooling system that serves to reject heat of a component to air driven by one or more system-level air movers (e.g., fans) for cooling multiple components of an information handling system in addition to the peripheral component. Another traditional approach may include an “active” cooling system that uses liquid cooling, in which a heat-exchanging cold plate is thermally coupled to the component, and a chilled fluid is passed through conduits internal to the cold plate to remove heat from the component.

However, one disadvantage to using liquid cooling is that components of the liquid cooling system (e.g., fluid fittings, fluid joints, hoses or other fluidic conduits, pumps, cold plates, etc.) may develop leaks over time due to vibration, thermal cycles, or aging. Liquid leaks within an information handling system may cause corrosion to components of the information handling system and/or damage to electrical or electronic circuitry of the information handling system.

While solutions exist for leak detection, often such solutions are ineffective. For example, one traditional solution is the use of a leak detection cable or “rope”, which may comprise a twisted pair cable having an electrical impedance that changes in the presence of increased moisture on the leak detection cable. Due to the expense of leak detection cables, more recent improvements have used flexible printed circuit board (PCB) circuitry as leak-detection circuits in lieu of leak detection cables.

For best panelization efficiency, these flexible PCBs are often long, narrow, and substantially straight. However, while long and narrow flex circuits are easily bent around one axis, they often resist in-plane bends. To be useful as a replacement for leak detection cables, it may be desirable to match the mechanical properties of flexible PCBs to leak detection cables (e.g., ability to bend in any direction).

### SUMMARY

In accordance with the teachings of the present disclosure, the disadvantages and problems associated with detecting leaks of fluid from liquid cooling systems may be substantially reduced or eliminated.

In accordance with embodiments of the present disclosure, an information handling system may include an information handling resource, a liquid cooling system for providing cooling of the information handling resource, and a leak detection system for detecting a leak of fluid from the liquid cooling system. The leak detection system may include a leak detection circuit formed into a helical shape and having at least one moisture-sensitive portion configured to detect the presence of moisture proximate to the leak detection circuit and circuitry configured to communicate one or more electrical signals indicative of the presence or absence of moisture proximate to the leak detection circuit and a moisture wicking material mechanically coupled to the leak detection circuit and configured to transport moisture within the moisture wicking material to the at least one moisture-sensitive portion of the leak detection circuit.

In accordance with these and other embodiments of the present disclosure, a leak detection system for detecting a leak of fluid may include a leak detection circuit formed into a helical shape and having at least one moisture-sensitive portion configured to detect the presence of moisture proximate to the leak detection circuit and circuitry configured to communicate one or more electrical signals indicative of the presence or absence of moisture proximate to the leak detection circuit and a moisture wicking material mechanically coupled to the leak detection circuit and configured to transport moisture within the moisture wicking material to the at least one moisture-sensitive portion of the leak detection circuit.

In accordance with these and other embodiments of the present disclosure, a method may include forming a leak detection circuit into a helical shape, the leak detection circuit having at least one moisture-sensitive portion configured to detect the presence of moisture proximate to the leak detection circuit and circuitry configured to communicate one or more electrical signals indicative of the presence or absence of moisture proximate to the leak detection circuit and mechanically coupling a moisture wicking material to the leak detection circuit and configured to transport moisture within the moisture wicking material to the at least one moisture-sensitive portion of the leak detection circuit.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2A illustrates selected portions of a leak detection system, in accordance with embodiments of the present disclosure;

FIG. 2B illustrates the leak detection system of FIG. 2A formed into a helical shape by twisting the leak detection circuit of the leak detection system about an axis along the length of the leak detection circuit, in accordance with embodiments of the present disclosure;

FIG. 3 illustrates a clip for retaining a leak detection circuit within an information handling system, in accordance with embodiments of the present disclosure;

FIG. 4 illustrates a retention feature for retaining a leak detection circuit within an information handling system, in accordance with embodiments of the present disclosure;

FIG. 5 illustrates selected portions of another leak detection system formed into a helical shape by coiling the leak detection circuit of the leak detection system around a core of moisture wicking material, in accordance with embodiments of the present disclosure;

FIG. 6 illustrates selected portions of yet another leak detection system formed into a helical shape by coiling the leak detection circuit of the leak detection system around a core of moisture wicking material, in accordance with embodiments of the present disclosure; and

FIG. 7 illustrates selected portions of an additional leak detection system formed into a helical shape by coiling the leak detection circuit of the leak detection system around a core of moisture wicking material, in accordance with embodiments of the present disclosure.

### DETAILED DESCRIPTION

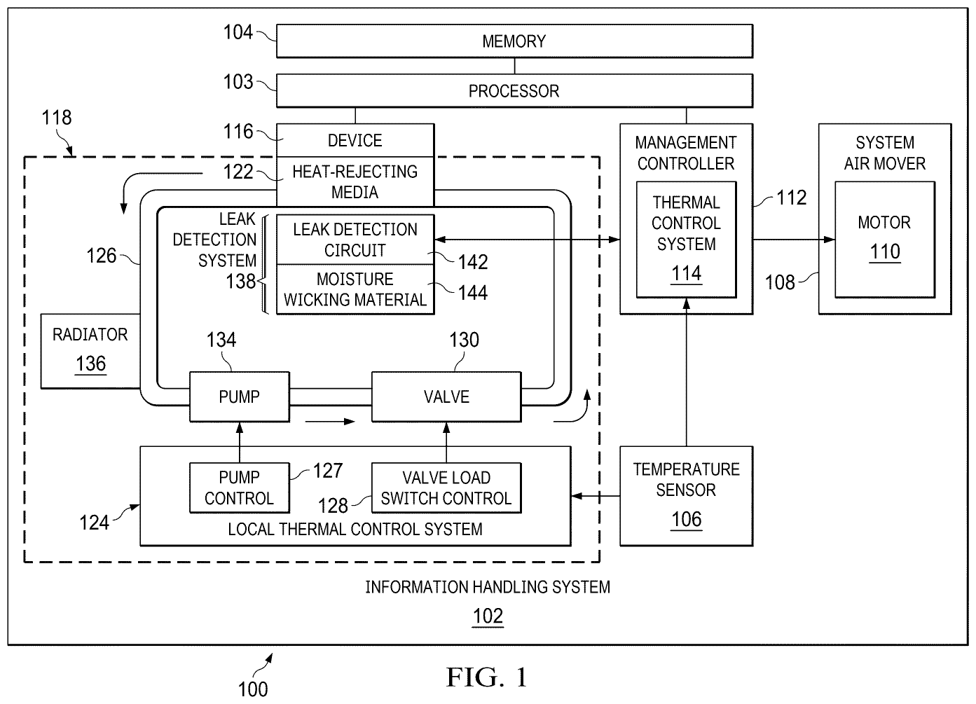

Preferred embodiments and their advantages are best understood by reference to FIGS. 1 through 7, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may include a chassis 100 housing a processor 103, a memory 104, a temperature sensor 106, a system air mover 108, a management controller 112, a device 116, and a liquid cooling system 118 comprising a leak detection system 138.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

System air mover 108 may include any mechanical or electro-mechanical system, apparatus, or device operable to move air and/or other gases in order to cool information handling resources of information handling system 102. In some embodiments, system air mover 108 may comprise a fan (e.g., a rotating arrangement of vanes or blades which act on the air). In other embodiments, system air mover 108 may comprise a blower (e.g., a centrifugal fan that employs rotating impellers to accelerate air received at its intake and change the direction of the airflow). In these and other embodiments, rotating and other moving components of system air mover 108 may be driven by a motor 110. The rotational speed of motor 110 may be controlled by an air mover control signal communicated from thermal control system 114 of management controller 112. In operation, system air mover 108 may cool information handling resources of information handling system 102 by drawing cool air into an enclosure housing the information handling resources from outside the chassis, expel warm air from inside the enclosure to the outside of such enclosure, and/or move air across one or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 106), and based on such signals, calculate an air mover driving signal to maintain an appropriate level of cooling, increase cooling, or decrease cooling, as appropriate, and communicate such air mover driving signal to system air mover 108. In these and other embodiments, thermal control system 114 may be configured to receive information from other information handling resources and calculate the air mover driving signal based on such received information in addition to temperature information. For example, as described in greater detail below, thermal control system 114 may receive configuration data from device 116 and/or other information handling resources of information handling system 102, which may include thermal requirement information of one or more information handling resources. In addition to temperature information collected from sensors within information handling system 102, thermal control system 114 may also calculate the air mover driving signal based on such information received from information handling resources.

Temperature sensor 106 may be any system, device, or apparatus (e.g., a thermometer, thermistor, etc.) configured to communicate a signal to processor 103 or another controller indicative of a temperature within information handling system 102. In many embodiments, information handling system 102 may comprise a plurality of temperature sensors 106, wherein each temperature sensor 106 detects a temperature of a particular component and/or location within information handling system 102.

Device 116 may comprise any component information handling system of information handling system 102, including without limitation processors, buses, memories, I/O devices and/or interfaces, storage resources, network interfaces, motherboards, integrated circuit packages; electro-mechanical devices, displays, and power supplies.

Oftentimes, an architecture of information handling system 102 may be such that device 116 may be significantly downstream of system air mover 108 that it may be significantly more effective for device 116 to be cooled using liquid cooling system 118. Alternatively, device 116 may generate heat at a rate that air-based cooling is insufficient to cool device 116. As shown in FIG. 1, liquid cooling system 118 may include a local thermal control system 124, heat-rejecting media 122, pump 134, radiator 136, valve 130, fluidic conduits 126, and a leak detection system 138.

Local thermal control system 124 may be communicatively coupled to temperature sensor 106, and may include any system, device, or apparatus (e.g., a processor, controller, etc.) configured to control components of liquid cooling system 118 for cooling a temperature of one or more information handling resources of information handling system 102. For example, local thermal control system 124 may be configured to control pump 134 and/or valve 130 based on thermal data sensed by temperature sensor 106, so as to maintain a safe operating temperature for one or more information handling resources. Accordingly, local thermal control system 124 may include a pump control subsystem 127 for controlling operation of pump 134 (e.g., a pressure applied to coolant fluid in fluidic conduits 126 for moving such fluid through fluidic conduits 126) and a valve load switch control subsystem 128 for controlling operation of valve 130 (e.g., opening or closing valve 130, controlling an aperture of valve 130, etc.).

Pump 134 may be fluidically coupled to one or more fluidic conduits 126 and may comprise any mechanical or electro-mechanical system, apparatus, or device operable to produce a flow of fluid (e.g., fluid in one or more conduits 126). For example, pump 134 may produce fluid flow by applying a pressure to fluid in fluidic conduits 126. As described above, operation of pump 134 may be controlled by pump control subsystem 127 which may control electro-mechanical components of pump 134 in order to produce a desired rate of coolant flow.

Radiator 136 may include any device, system or apparatus configured to transfer thermal energy from one medium (e.g., fluid within a fluidic conduit 126) to another (e.g., air external to chassis 100) for the purpose of cooling and heating. In some embodiments, radiator 136 may include fluidic channels and/or conduits in at least a portion of radiator 136. Such fluidic channels and/or conduits may be fluidically coupled to one or more of fluidic conduits 126 and pump 134.

Valve 130 may include any device, system or apparatus that regulates, directs, and/or controls the flow of a fluid (e.g., a coolant liquid in fluidic conduits 126) by opening, closing, or partially obstructing one or more passageways. When valve 130 is open, coolant liquid may flow in a direction from higher pressure to lower pressure. As described above, the operation of valve 130 (e.g., opening and closing, size of an aperture of valve 130) may be controlled by valve load switch control subsystem 128.

In operation, pump 134 may induce a flow of liquid (e.g., water, ethylene glycol, propylene glycol, or other coolant) through various fluidic conduits 126 of information handling system 102, valve 130 and/or radiator 136. As fluid passes by heat-rejecting media 122 in a fluidic conduit 126 proximate to device 116, heat may be transferred from device 116 to heat-rejecting media 122 and from heat-rejecting media 122 to the liquid coolant in fluidic conduit 126. As such heated coolant flows by radiator 136, heat from the coolant may be transferred from the coolant to air ambient to chassis 100, thus cooling the fluid.

Heat-rejecting media 122 may include any system, device, or apparatus configured to transfer heat from an information handling resource (e.g., device 116, as shown in FIG. 1), thus reducing a temperature of the information handling resource. For example, heat-rejecting media 122 may include a solid thermally coupled to the information handling resource (e.g., heatpipe, heat spreader, heatsink, finstack, etc.) such that heat generated by the information handling resource is transferred from the information handling resource.

Leak detection system 138 may be communicatively coupled to management controller 112 and may comprise any system, device, or apparatus configured to detect a presence of a leak of the cooling fluid of liquid cooling system 118, and generate one or more electrical signals indicative of whether such a leak is present. As shown in FIG. 1, leak detection system 138 may include a leak detection circuit 142 and moisture wicking material 144.

Leak detection circuit 142 may comprise any system, device, or apparatus configured to detect the presence or absence of moisture proximate to leak detection circuit 142 and communicate one or more signals to management controller 112 indicative of the presence or absence of a leak of cooling fluid from liquid cooling system 118. Accordingly, leak detection circuit 142 may be located within information handling system 102 at locations which may be susceptible to a liquid leak, such as proximate to heat-rejecting media 122.

In some embodiments, leak detection circuit 142 may comprise a flexible printed circuit board or a thin printed circuit board. Such printed circuit board may include one or more exposed conductive traces, such that leak detection circuit 142 may have an impedance (e.g., a resistive impedance, reactive impedance, or complex impedance) that may vary based on whether moisture is present on such exposed conductive traces. For instance, in some embodiments, such exposed electrical traces may have an electrical resistance that decreases in the presence of increased moisture present on such exposed conductive traces and increases in the presence of decreased moisture present on such exposed electrical traces. In addition, leak detection circuit 142 may also include other electrical circuitry and/or logic that is capable of detecting such changes in electrical impedances and communicating one or more signals to management controller 112 based on such detected changes, such one or more signals indicative of the presence or absence of a leak of cooling fluid from liquid cooling system 118. Further, as described in greater detail below, leak detection circuit 142 may be arranged in a helical shape in order to mechanically behave in a manner akin to a traditional leak detection cable.

Moisture wicking material 144 may be formed over all or part of a surface of leak detection circuit 142, including any portion of leak detection circuit 142 having exposed conductive traces. Moisture wicking material 144 may comprise felt, textile fiber, and/or any other suitable material configured to transport at least a portion of liquid that contacts moisture wicking material 144 from one portion of moisture wicking material 144 to another portion of moisture wicking material 144, thus increasing the likelihood that liquid contacting moisture wicking material 144 is transported to portions of leak detection circuit 142 having exposed conductive traces and will effect a change in impedance associated with such exposed conductive traces. In some embodiments, moisture wicking material 144 may include, or may be treated with, one or more substances in order to increase capillary action of moisture wicking material 144, enhance leak detection by increasing magnitude of a change in electrical impedance associated with exposed traces of leak detection circuit 142, and/or change color when coming into contact with liquid.

In addition to processor 103, memory 104, temperature sensor 106, air mover 108, management controller 112, device 116, liquid cooling system 118, and leak detection system 138, information handling system 102 may include one or more other information handling resources. In addition, for the sake of clarity and exposition of the present disclosure, FIG. 1 depicts only one system air mover 108 and one device 116. In embodiments of the present disclosure, information handling system 102 may include any number of system air movers 108 and devices 116. Furthermore, for the sake of clarity and exposition of the present disclosure, FIG. 1 depicts device 116 including liquid cooling system 118 for cooling of device 116. However, in some embodiments, approaches similar or identical to those used to cool device 116 as described herein may be employed to provide cooling of processor 103, memory 104, management controller 112, and/or any other information handling resource of information handling system 102.

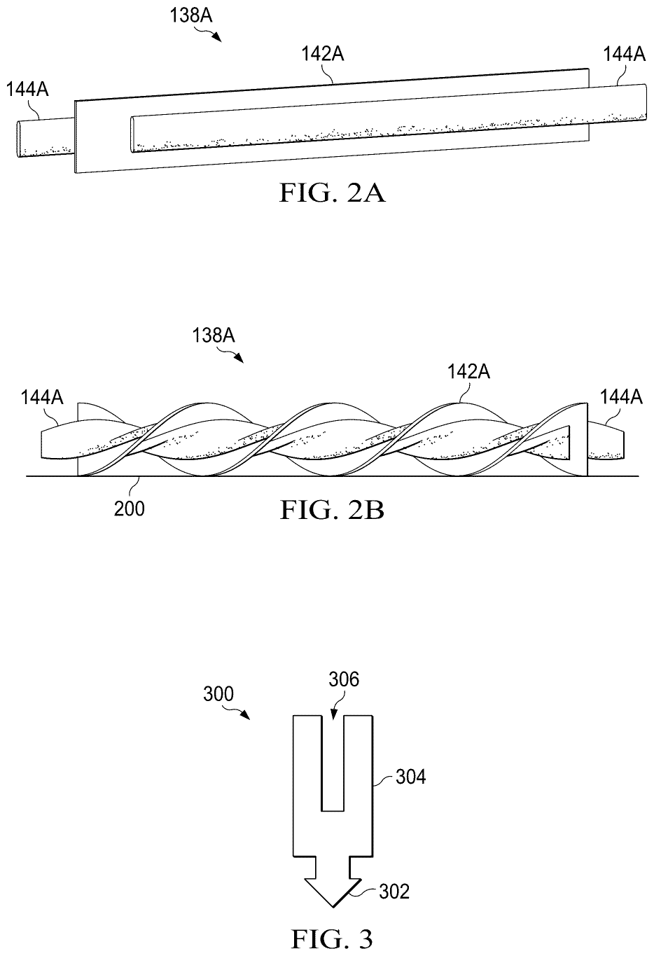

FIG. 2A illustrates selected portions of a leak detection system 138A, in accordance with embodiments of the present disclosure. Leak detection system 138A as shown in FIGS. 2A and 2B may be used to implement leak detection system 138 depicted in FIG. 1. As shown in FIG. 2A, leak detection system 138A may include a leak detection circuit 142A (to implement leak detection circuit 142 of FIG. 1) and moisture wicking material 144A (to implement moisture wicking material 144 of FIG. 1). As also shown in FIG. 2A, moisture wicking material 144A may be formed on or attached to both sides of leak detection circuit 142A, which may be implemented using a flexible circuit board.

FIG. 2B illustrates leak detection system 138A formed into a helical shape by twisting of leak detection circuit 142A about an axis along the length (i.e., the longest dimension) of leak detection circuit 142A, in accordance with embodiments of the present disclosure. Such twisting into the helical shape shown in FIG. 2B may enable leak detection system 138A to have “rope-like” mechanical behavior similar to a traditional leak detection cable. In addition, such helical geometry may maximize a detection surface while ensuring that contact of leak detection system 138A with sheet metal 200 of the interior of chassis 100 may occur only along the edges of leak detection circuit 142A, which may be insulated. The helical shape also provides for a periodic reversal of the sensing area of leak detection circuit 142A, which may minimize noise and/or other proximity effects due to nearby objects. In addition to wicking moisture, moisture wicking material 144A may also provide mechanical structure to leak detection system 138A, including prevention of kinking within the twisted flexible circuit board of leak detection circuit 142A.

FIG. 3 illustrates a clip 300 for retaining leak detection system 138A within information handling system 102, in accordance with embodiments of the present disclosure. As shown in FIG. 3, clip 300 may include a chassis engagement feature 302 coupled to a U-shaped body 304 with an opening 306 formed in U-shaped body 304. To route and retain leak detection system 138A, each of one or more clips 300 may be mechanically coupled to a corresponding feature of the interior of chassis 100 (e.g., snapped into a hole formed in sheet metal of chassis 100) and a portion of leak detection system 138A may be retained within opening 306 of each of the one or more clips 300. Accordingly, by appropriately spacing clips 300 within chassis 100, detection paths of leak detection system 138A may be formed in any suitable routing. Further, opening 306 may be configured to (e.g., sized and shaped to) maintain the twist of leak detection system 138A.

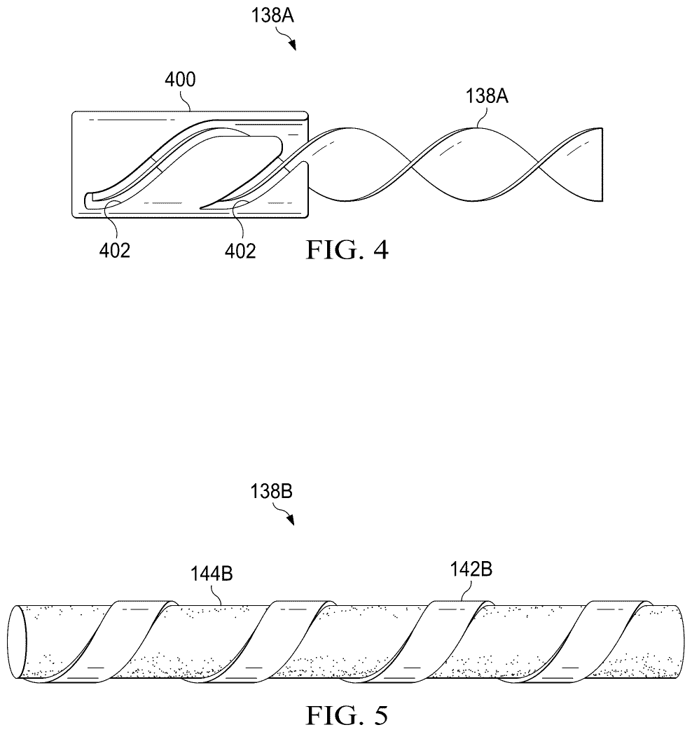

FIG. 4 illustrates a retention feature 400 for retaining leak detection system 138A within information handling system 102, in accordance with embodiments of the present disclosure. Retention feature 400 may comprise an end cap for leak detection system 138A, configured to (e.g., sized and shaped to) couple to an end of leak detection system 138A and may include features 402 (e.g., openings and/or slots) to maintain the twisted helical shape of leak detection system 138A.

FIG. 5 illustrates selected portions of another leak detection system 138B formed into a helical shape by coiling leak detection circuit 142B around a core of moisture wicking material 144B, in accordance with embodiments of the present disclosure. Leak detection system 138B as shown in FIG. 5 may be used to implement leak detection system 138 depicted in FIG. 1. Similarly, leak detection circuit 142B and moisture wicking material 144B may implement leak detection circuit 142 and moisture wicking material 144 of FIG. 1, respectively. As shown in FIG. 5, leak detection circuit 142B may be wrapped around moisture wicking material 144B such that edges of leak detection circuit 142B do not contact one another, creating space between adjacent edges of leak detection circuit 142B. Such coiling into the helical shape shown in FIG. 5 may enable leak detection system 138B to have “rope-like” mechanical behavior similar to a traditional leak detection cable.

In leak-detection system 138B, moisture wicking material 144B may provide a significant portion of the mechanical structure of leak-detection system 138B, supporting leak-detection system 138B from its center and preventing bulging. Leak-detection system 138B may provide for a large detection surface, and may also provide for a periodic reversal of the sensing area of leak detection circuit 142B, which may minimize noise and/or other proximity effects due to nearby objects. In some embodiments, sensing circuitry may be formed on only the inside surface of leak detection circuit 142B, for use in environments in which the outside surface of leak detection circuit 142B may contact metal.

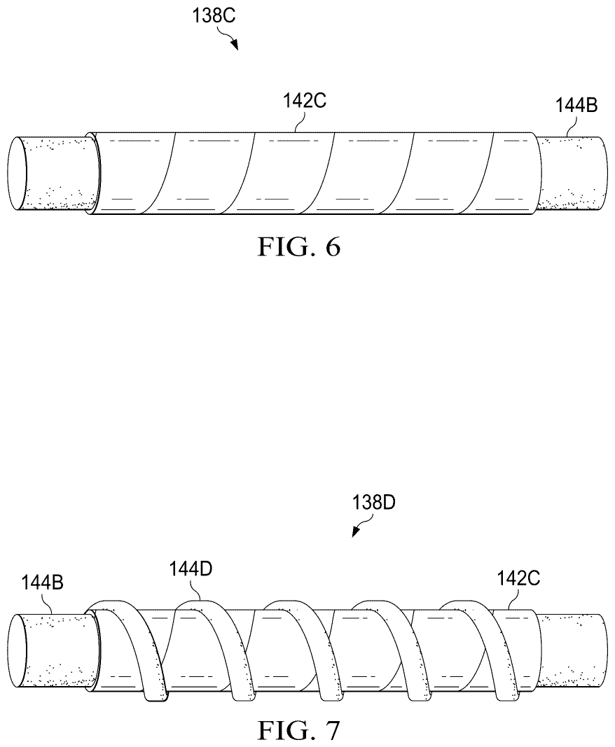

FIG. 6 illustrates selected portions of another leak detection system 138C formed into a helical shape by coiling leak detection circuit 142C around a core of moisture wicking material 144B, in accordance with embodiments of the present disclosure. Leak detection system 138C as shown in FIG. 6 may be used to implement leak detection system 138 depicted in FIG. 1. Similarly, leak detection circuit 142C and moisture wicking material 144B may implement leak detection circuit 142 and moisture wicking material 144 of FIG. 1, respectively. As shown in FIG. 6, leak detection circuit 142C may be wrapped around moisture wicking material 144B such that edges of leak detection circuit 142C may contact or partially overlap one another. Such coiling into the helical shape shown in FIG. 6 may enable leak detection system 138C to have “rope-like” mechanical behavior similar to a traditional leak detection cable. Leak detection system 138C of FIG. 6 may be similar in many respects to leak detection system 138B of FIG. 5, except that leak detection system 138C may include leak detection circuit 142C in lieu of leak detection circuit 142B.

FIG. 7 illustrates selected portions of another leak detection system 138D formed into a helical shape by coiling leak detection circuit 142C around a core of moisture wicking material 144B, in accordance with embodiments of the present disclosure. Leak detection system 138D as shown in FIG. 7 may be used to implement leak detection system 138 depicted in FIG. 1. Leak detection system 138D of FIG. 7 may be similar in many respects to leak detection system 138C of FIG. 6, except that leak detection system 138D may also include moisture wicking material 144D wrapped or otherwise placed on the outside of leak detection circuit 142C. Such additional moisture wicking material 144D may increase detection sensitivity and may provide further structure in order to ensure maintaining the coil shape of leak detection circuit 142C around moisture wicking material 144B.

For purposes of clarity and exposition, the cooling system described above is an active cooling system, meaning the cooling system includes a pump and operates in a closed loop. However, the systems and methods herein are also suitable for use in passive systems and/or in an information technology loop, wherein pumping of cooling fluid is centralized in a cooling distribution unit (CDU) and cooling fluid may flow into and out of an information handling system through hoses, tubes, and other fluidic conduits coupled to a manifold in an information handling system rack or other enclosure.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
an information handling resource;
a liquid cooling system for providing cooling of the information handling resource; and
a leak detection system for detecting a leak of fluid from the liquid cooling system, the leak detection system comprising:
a leak detection circuit formed into a helical shape and having at least one moisture-sensitive portion configured to detect the presence of moisture proximate to the leak detection circuit and circuitry configured to communicate one or more electrical signals indicative of the presence or absence of moisture proximate to the leak detection circuit; and
a moisture wicking material mechanically coupled to the leak detection circuit and configured to transport moisture within the moisture wicking material to the at least one moisture-sensitive portion of the leak detection circuit.

2. The information handling system of claim 1, wherein the helical shape is formed as a twisting of the leak detection circuit about an axis along the length of the leak detection circuit.

3. The information handling system of claim 2, further comprising at least one clip for retaining the leak detection system within the information handling system, wherein each clip of the at least one clip comprises:
an attachment feature for mechanically coupling to a chassis of the information handling system; and
a body mechanically coupled to the attachment feature and comprising an opening configured to retain the leak detection system.

4. The information handling system of claim 3, wherein the opening is further configured to maintain the twisting of the leak detection circuit.

5. The retention feature of claim 2, further comprising a retention feature configured to couple to an end of the leak detection system and comprising features configured to maintain the twisting of the leak detection circuit.

6. The information handling system of claim 1, wherein the helical shape is formed as a coiling of the leak detection circuit about a core formed by the moisture wicking material.

7. The information handling system of claim 6, wherein the coiling is such that space exists between adjacent edges of the leak detection circuit.

8. The information handling system of claim 6, wherein the coiling is such that adjacent edges of the leak detection circuit are in contact or overlapping with one another.

9. The information handling system of claim 6, wherein the leak detection system further comprises additional wicking material mechanically coupled to a first surface of the leak detection circuit opposite of a second surface of the leak detection surface proximate to the core formed by the moisture wicking material.

10. A leak detection system for detecting a leak of fluid, the leak detection system comprising:
a leak detection circuit formed into a helical shape and having at least one moisture-sensitive portion configured to detect the presence of moisture proximate to the leak detection circuit and circuitry configured to communicate one or more electrical signals indicative of the presence or absence of moisture proximate to the leak detection circuit; and
a moisture wicking material mechanically coupled to the leak detection circuit and configured to transport moisture within the moisture wicking material to the at least one moisture-sensitive portion of the leak detection circuit.

11. The leak detection system of claim 10, wherein the helical shape is formed as a twisting of the leak detection circuit about an axis along the length of the leak detection circuit.

12. The leak detection system of claim 10, wherein the helical shape is formed as a coiling of the leak detection circuit about a core formed by the moisture wicking material.

13. The leak detection system of claim 12, wherein the coiling is such that space exists between adjacent edges of the leak detection circuit.

14. The leak detection system of claim 12, wherein the coiling is such that adjacent edges of the leak detection circuit are in contact or overlapping with one another.

15. The leak detection system of claim 12, further comprising additional wicking material mechanically coupled to a first surface of the leak detection circuit opposite of a second surface of the leak detection surface proximate to the core formed by the moisture wicking material.

16. A method, comprising:
forming a leak detection circuit into a helical shape, the leak detection circuit having at least one moisture-sensitive portion configured to detect the presence of moisture proximate to the leak detection circuit and circuitry configured to communicate one or more electrical signals indicative of the presence or absence of moisture proximate to the leak detection circuit; and
mechanically coupling a moisture wicking material to the leak detection circuit and configured to transport moisture within the moisture wicking material to the at least one moisture-sensitive portion of the leak detection circuit.

17. The method of claim 16, further comprising forming the helical shape by twisting of the leak detection circuit about an axis along the length of the leak detection circuit.

18. The method of claim 17, further comprising retaining the leak detection system to a chassis using at least one clip, wherein the clip comprises:
an attachment feature for mechanically coupling to the chassis; and
a body mechanically coupled to the attachment feature and comprising an opening configured to retain the leak detection system.

19. The method of claim 18, further comprising maintaining the twisting of the leak detection circuit within the opening.

20. The method of claim 17, further comprising coupling a retention feature to an end of the leak detection system, wherein the retention feature comprises features configured to maintain the twisting of the leak detection circuit.

21. The method of claim 16, further comprising forming the helical shape as a coiling of the leak detection circuit about a core formed by the moisture wicking material.

22. The method of claim 21, further comprising forming the helical shape such that space exists between adjacent edges of the leak detection circuit.

23. The method of claim 21, further comprising forming the helical shape such that adjacent edges of the leak detection circuit are in contact or overlapping with one another.

24. The method of claim 21, further comprising mechanically coupling additional wicking material to a first surface of the leak detection circuit opposite of a second surface of the leak detection surface proximate to the core formed by the moisture wicking material.
